(19) United States
(12) Patent Application Publication
(10) Pub. No.: US 2026/0204515 A1
(43) Pub. Date: Jul. 16, 2026

(54) System and Method for Optimizing Ion Energy Distribution in Plasma Process Chambers Using Tailored Waveform Generators with Multi-Slope Ramping Profiles

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 19/023,229

(22) Filed: Jan. 15, 2025

(51) Int. Cl. H01J 37/32

(52) U.S. Cl. CPC H01J 37/32128; H01J 37/321; H01J 37/32146; H01J 2237/334

(57) ABSTRACT

Disclosed herein is a real-time optimization system for a plasma process system, specifically focusing on a tailored waveform generator coupled to a chuck. The system incorporates a system controller that divides the process recipe into a setting phase and a processing phase. During the setting phase, optimized slope schemes for voltage waveforms are determined to improve plasma processing performance. The disclosed system features a novel slope scheme comprising multiple slopes, offering enhanced flexibility and precision in controlling ion energy distribution.

### FIELD OF INVENTION

This invention relates to plasma process systems used in semiconductor manufacturing and related fields. Specifically, it pertains to the real-time optimization of tailored voltage waveforms, enabling precise management of ion energy and current during plasma-enhanced processes, such as etching, within a plasma process chamber.

### BACKGROUND

Plasma process systems are fundamental in semiconductor manufacturing, supporting applications such as etching, deposition, and cleaning. Achieving uniformity and precision in these processes requires precise control of plasma properties, particularly ion energy and ion current density, which directly impact substrate quality and processing outcomes.

These systems employ radio frequency (RF) power to sustain plasma and tailored waveform biases to regulate ion energy distribution at the wafer surface. The slope of the descending step in the tailored waveform is particularly crucial, as it influences the wafer surface potential and, consequently, ion energy and current. This is especially important in complex processes such as dielectric film etching.

Conventional approaches rely on predefined bias profiles based on models or historical data, which often fail to adapt to real-time variations in process conditions, substrate properties, or chamber states. Such limitations reduce the reliability and precision of process outcomes.

Optimizing and dynamically adjusting the waveform bias, including its descending step with multiple distinct slopes, addresses these challenges by maintaining consistent ion energy distribution in real time. This requires a robust system capable of evaluating and applying optimal waveform parameters dynamically to ensure stable processing conditions while adapting to variations.

Thus, there is a need for a system and method that enables real-time, dynamic control over waveform bias, offering precise and consistent plasma processing outcomes. Such a system must enhance adaptability to diverse processing conditions, improve reliability, and deliver high-quality results in plasma-assisted applications.

### SUMMARY

The present invention provides a system and method for optimizing and controlling tailored voltage waveforms in a plasma process chamber to achieve precise and consistent ion energy distribution during plasma-enhanced processes, such as etching.

In one embodiment, the system employs a tailored waveform generator coupled to a chuck, where the ramp step of the waveform comprises multiple linear descending voltage steps, each characterized by a distinct slope. This configuration provides enhanced control over ion energy distribution by reducing variations and narrowing ion energy spread.

In another embodiment, the system includes a tailored waveform generator and a system controller that divides the process recipe into a setting phase and a processing phase. During the setting phase, the system controller generates a pulse train containing both single-slope and multi-slope ramping profiles to explore various slope configurations. Real-time current sensing is performed to measure the output current of the bias unit during each pulse. The optimized slope or slope scheme is identified based on criteria such as minimal variation in the output current as a function of slope changes.

The optimized slopes or slope schemes are applied in the processing phase to ensure consistent wafer surface potential and ion energy throughout the plasma process. The system stores optimized slopes for future use, reducing the need for repetitive optimization and enhancing process reproducibility.

The integration of multi-slope ramping profiles (MSRP) offers significant advantages over traditional single-slope methods, including improved control over ion energy distribution, adaptability to varying plasma conditions, and enhanced outcomes in high-precision plasma processes. By combining real-time optimization with practical utility, the invention establishes a robust framework for reliable, repeatable, and high-quality plasma-assisted manufacturing.

### BRIEF DESCRIPTIONS OF THE DRAWINGS

FIG. 1A: Illustrates a process system equipped with a tailored waveform generator functioning as a bias unit for a chuck.

FIG. 1B: Presents an equivalent electrical circuit of a plasma process chamber, incorporating the tailored waveform bias.

FIG. 1C: Depicts an example of a tailored waveform with a single slope for the ramp step.

FIG. 1D: Depicts an example of a tailored waveform with a multi-slope ramping profile.

FIG. 2A: Represents an embodiment of a tailored waveform bias integrated with real-time optimization capabilities.

FIG. 2B: Exhibits exemplary pulse trains utilized during the setting phase and the processing phase.

FIG. 3: Illustrates an embodiment of a tailored waveform bias implemented with a switched-mode power converter and a current source, configured to generate a multi-slope ramping profile.

FIG. 4: Displays a flowchart delineating a process for determining the optimized slope scheme for ramp steps in a tailored waveform.

FIG. 5: Illustrates a flowchart embodying a method to generate optimized slope schemes for a process recipe, addressing steps that require varied ion currents.

### DETAILED DESCRIPTIONS

This section delves into the detailed embodiments of the invention, providing clarity on the inventive concept while encompassing potential modifications and variations consistent with the claims. Key terms and components are defined as follows:
Process System: Equipment for semiconductor manufacturing processes, such as etching, deposition, and cleaning.
Plasma Process Chamber: A vacuum chamber specifically designed for plasma-based processes.
Plasma Source: A device that generates plasma. Examples include:
   Inductively Coupled Plasma (ICP): Plasma generated using an RF magnetic field from a coil.
   Transformer Coupled Plasma (TCP): Plasma generated using RF energy delivered through a planar coil.
   Capacitively Coupled Plasma (CCP): Plasma generated using RF power applied across electrodes.
Tailored Waveform Generator: A device generating custom electrical waveforms, including multi-slope ramping profiles, to optimize ion energy distribution.
Multi-Slope Ramping Profile (MSRP): A waveform characterized by multiple distinct slopes in a descending step for precise ion energy control.
Switched-Mode Power Converter (SMPC): An electrical device that switches components rapidly for efficient power conversion.
Current Source: A circuit or device delivering a constant current for precise waveform control.
Pulse Train: A sequence of pulses with controlled amplitude, timing, and slope to form tailored waveforms.
Setting Phase: A phase where the system controller determines optimized slopes for ramp steps in the tailored waveform bias.
Processing Phase: A phase where the optimized slopes are applied to execute the process recipe.
Chuck: A component holding the wafer during processing, coupled to a bias unit to apply voltage for ion acceleration.
System Controller: The central unit managing the system's operations, including real-time waveform optimization.
Process Recipe: A set of instructions defining parameters for semiconductor manufacturing processes.

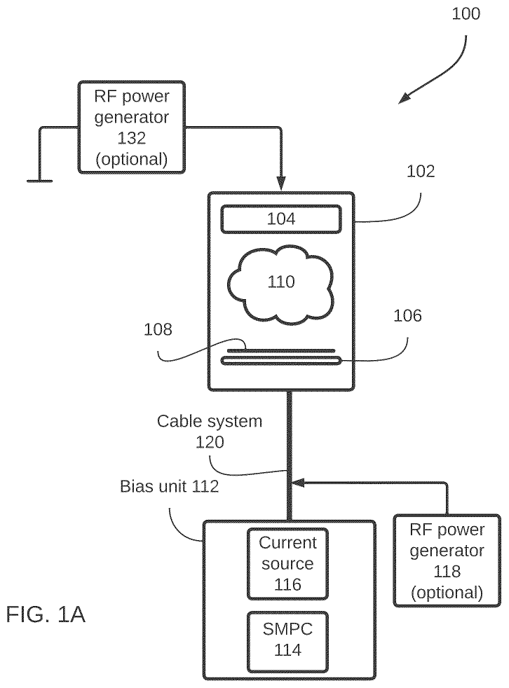

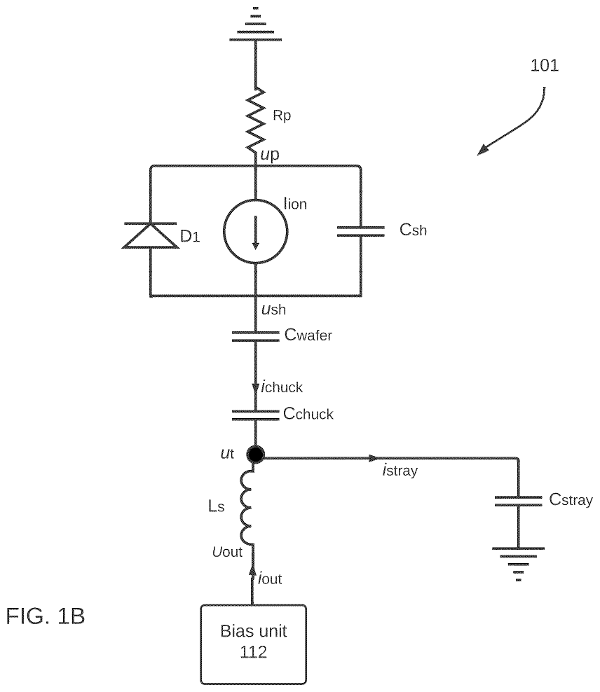

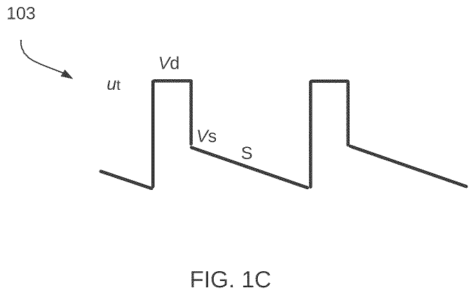

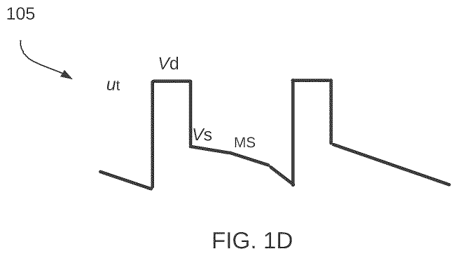

FIG. 1A illustrates an exemplary process system 100 incorporating a plasma process chamber 102. The chamber 102 establishes a vacuum environment conducive to various processing operations. Although not shown, process gases or precursors are introduced into the chamber via a designated delivery unit, while reaction byproducts are evacuated using a vacuum pump.

In some embodiments, a capacitively coupled plasma (CCP) source is utilized. Here, components 104 and 106 function as electrodes for the capacitor, receiving RF power from either the top or bottom of the chamber. Within the context of this disclosure, the CCP source, in tandem with the bias unit 112, serves as an example to elucidate the inventive concept across diverse embodiments without restricting the invention's scope.

In the CCP configuration, RF power is channeled to the electrodes, generating an electromagnetic field within the chamber 102. The gases within the chamber are ignited, yielding a plasma 110 composed of electrons, ions, and neutrals, essential for processes like etching a wafer 108 secured by a chuck 106. In modern plasma etching systems, the bias unit 112 is frequently employed to increase ion energy through the sheath. The bias unit 112 may include a tailored waveform generator, which further comprises a switched-mode power converter (SMPC) 114 and a current source 116. The bias unit 112 is coupled to the chuck 106 via a cable system 120. An RF power generator 118 may also be connected to the chuck 106 to supply additional RF power for plasma generation.

In alternative embodiments, the plasma source 104 can adopt various configurations based on the specific application. For example, the source 104 may be an inductively coupled plasma (ICP) source or a transformer coupled plasma (TCP) source. Typically, these sources are positioned adjacent to, yet isolated from, the chamber 102 through a dielectric window. In such configurations, RF power is conveyed to a coil from an RF power generator 132, creating an electromagnetic field within the chamber 102. In certain implementations, RF power is connected to the plasma chamber through matching networks (not shown in the figure).

FIG. 1B presents an equivalent electrical circuit 101 of the process system 100. The equivalent electrical circuit of the plasma process chamber using a tailored waveform bias has been discussed extensively by Yu et al. in “Equivalent electric circuit model of accurate ion energy control with tailored waveform biasing” (Plasma Sources Sci. Technol., Vol. 31, 2022, 035012). Upon ignition of plasma within the chamber 102, a sheath forms. This plasma sheath is modeled as a parallel connection of a diode D₁, an ion current source Iᵢₒₙ and a sheath capacitor Cₛₕ. An additional, relatively small sheath forms between an exposed portion of the chuck 106 and the chamber wall but is neglected for simplicity. The bias unit 112 is coupled to the plasma chamber through two serially connected capacitors: C_{chuck}, representing the chuck capacitor, and C_{wafer}, representing the wafer capacitor. A stray capacitor C_{stray} and stray inductance Lₛ are also incorporated into the model. In the model, a plasma resistor Rₚ determines the plasma potential uₚ.

FIG. 1C exemplifies a tailored waveform 103 with a single ramping slope, where Vₛ is the setting voltage, assumed to be negative, determining ion energy. Energetic positive ions strike the wafer surface during a process step. If the wafer surface is covered by a dielectric material layer, positive ions may accumulate on it. This accumulation alters the surface potential, diminishes ion energy and ion currents, and broadens the ion energy spread, which is undesirable in processes requiring precise control of ion energy distribution. Thus, a linear ramp step, characterized by a slope SS, toward a voltage more negative than Vₛ is necessary to maintain a constant wafer surface potential uₛₕ.

Ensuring that slope S is optimized is crucial for maintaining process consistency in the plasma process chamber. A slope steeper than the optimized value may cause overcompensation, increasing ion current, while a less-steep slope may cause under compensation, decreasing ion current. Both scenarios broaden ion energy distribution.

With the tailored waveform operating at the optimized slope, the wafer surface potential remains constant, and no current traverses through Cₛₕ. Consequently, the current flowing through the chuck equates to the ion current. Yu et al., in their study, demonstrated that the optimized slope SS can be determined by plotting the output current against the slope using the following equation:

$${C}_{eff , x} = \frac{{i}_{out , x + 1} - {i}_{out , x}}{{\dot{u}}_{out , x} - {\dot{u}}_{out , x}} , \qquad ( 1 )$$

Here, the optimized slope corresponds to the minimal C_{eff}. Alternatively, the optimized slope corresponds to minimal changes in the output current as a function of varied slope.

It should be noted that the rate of accumulation of positive charges on the surface may not be linear, particularly if the slope is not precise. Hence, a single slope may not yield the tightest ion energy distribution.

FIG. 1D depicts a tailored waveform 105 with a multi-slope ramping profile (MSRP), denoted as MS. The MSRP consists of multiple descending voltage slopes within a ramp step, each characterized by a distinct slope. This configuration enhances ion energy distribution by enabling finer control over the wafer surface potential and the plasma sheath dynamics. Unlike single-slope schemes, the use of multiple slopes compensates for non-linear charge accumulation on the wafer's dielectric surface. This results in a narrower ion energy distribution, reduced variations, and improved uniformity. Such improvements are critical for processes like high aspect ratio etching, where precise ion energy control ensures consistent etch profiles and mitigates risks of surface damage or defects.

Each slope in the MSRP contributes to maintaining the desired ion energy range throughout the ramp step. By carefully tailoring the slopes, the system prevents overcompensation or under compensation of the wafer surface potential, thereby reducing fluctuations in ion current and energy. This allows for a more uniform energy delivery across the wafer surface, essential for achieving reproducible and high-precision outcomes in plasma processing.

Building on the benefits of the MSRP, the invention further incorporates a real-time optimization system to dynamically determine the slopes and their configurations. The optimization process occurs during a setting phase, where a pulse train with varying slopes is applied, and the output current is measured for each slope. These measurements are analyzed to identify the slopes or slope schemes that result in the minimal variation in effective capacitance (C_{eff}) or output current, as described in Equation (1). The optimized slopes are then applied in a processing phase, ensuring consistent ion energy delivery even as plasma conditions evolve.

The real-time optimization process enables the system to adapt to variations in plasma density, sheath properties, and chamber conditions without requiring manual adjustments to the process recipe. This dynamic adaptability is particularly advantageous in multi-step recipes with varying plasma states, as it ensures that each state operates with optimized ion energy distribution. Additionally, the system compensates for gradual changes in chamber conditions, such as electrode wear or gas flow variations, maintaining stable performance over extended periods and reducing the need for recalibration.

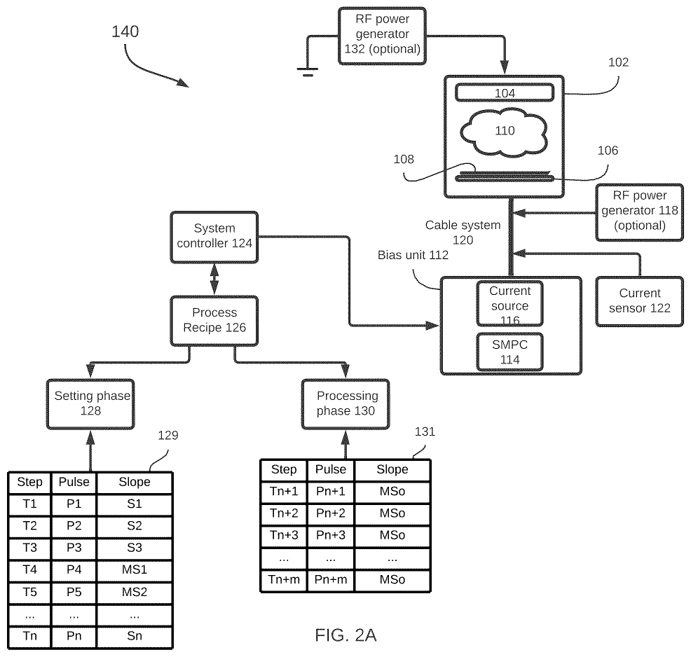

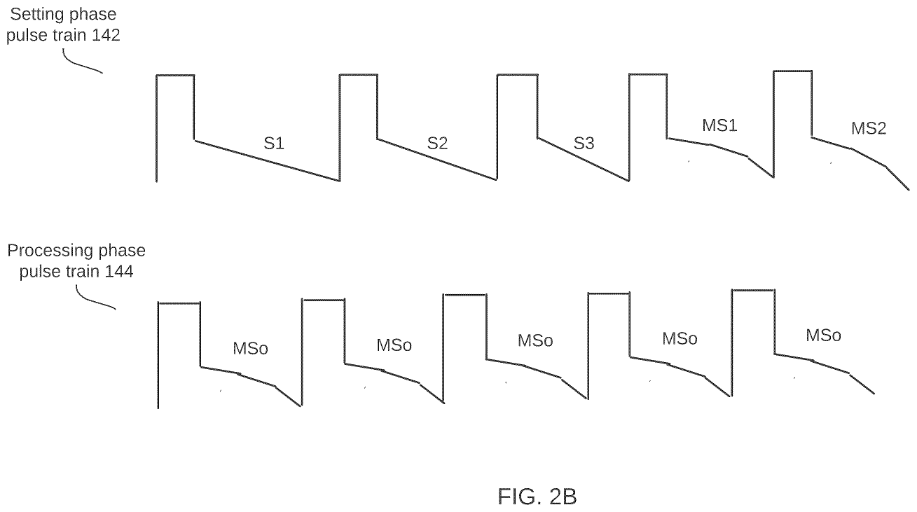

FIG. 2A illustrates an embodiment of a process system (140) with a tailored waveform bias as an implementation of the bias unit (112), furnished with real-time control capabilities. When contrasted with FIG. 1A, which depicts a conventional process system (100), differences are as follows:

A current sensor (122) is incorporated to measure the output current of the bias unit (112). The current sensor (122) can manifest in various forms; for instance, the current sensor (122) might be a Rogowski current sensor.

A system controller (124) bifurcates a process recipe (126) into a setting phase (128) and a processing phase (130). In the setting phase (128), the process recipe (126) is tabulated as (129) and includes a pulse train (142) with steps (T₁, T₂, T₃, . . . , Tₙ). The pulses in the pulse train (142) can be divided into two groups. For the first group, each step includes exemplarily a ramp step with a distinct slope (S₁, S₂, S₃) for each pulse (P₁, P₂, P₃). The pulse train (142) may cover an adequately broad range of slopes well beyond three slopes shown in FIG. 2A. For the second group, each step includes exemplarily a ramp step with multiple slopes (MS₁, MS₂) for each pulse (P₄, P₅). The pulse train (142) may cover an adequately broad range of MSRP schemes, well beyond two multi-slope schemes shown in FIG. 2A.

FIG. 2B exemplifies the pulse train (142) and (144). In some implementations, the pulse train (142) might be segmented into groups, each consisting of multiple pulses with a common single slope or common multi-slope scheme.

During the setting phase, the pulse train (142) is generated by the bias unit (112). The output current of the bias unit (112) is measured for each of the ramp steps of the pulse within the pulse train by the current sensor (122). For the pulses with MSRP, multiple currents are measured for a single pulse, each corresponds to a distinct slope. These measured currents are transmitted to the system controller (124), which analyzes them as a function of the slopes and determines the optimized slope or slope schemes corresponding to the minimal C_{eff} according to the Equation (1). For the pulse with the MSRP, C_{eff} may be averaged across the multiple slopes.

During the processing phase, the pulse train (144) consists of steps (Tₙ₊₁, Tₙ₊₂, Tₙ₊₃, . . . , Tₙ₊ₘ) with pulses (Pₙ₊₁, Pₙ₊₂, Pₙ₊₃, . . . , Pₙ₊ₘ), each having the same optimized slope Sₒ or the MSₒ for the ramp steps of the pulses within the pulse train (144), note MSₒ here represents the ramp with multiple distinct slopes.

It's vital to note that the pulse train (142) for the setting phase is significantly shorter than the pulse train (144) used during the processing phase. Thus, the effects of the varied slope in the setting phase on the on-wafer results are negligible.

A notable advantage of this system and method lies in the invisibility of the setting phase to a user of the process system (140). There is no necessity to modify a process recipe. The system controller (124) employs this novel method to optimize the slope or the slope scheme in an autonomous manner, thereby ensuring consistent ion current and energy in real time.

The system and method can be implemented in varied forms. For example, the setting phase can be interjected at various points in the processing phase where a change in ion current is anticipated due to evolving processing conditions. The setting phase could also be appended to the end of the process recipe to validate that the process conditions have been optimized.

In alternative implementations, groups of pulses, instead of single pulse, might be used to ascertain a relationship between the output current and the slope or the slope scheme, assisting in filtering out noise generated by either the measurement process or the plasma chamber itself.

In yet other implementations, the setting phase may be applied selectively for certain wafers, instead of universally for every wafer running the same process recipe. The optimized slope will be stored in the controller (124) for processing subsequent wafers.

In still other implementations, the setting phase can be designed as an independent setup test without mixing with the actual processing of a wafer. The measured current as a function of the slopes can be recorded in a storage medium of the system controller (124). The optimized slope can be computed and adopted by a process recipe before processing of the wafer.

It should also be noted that a modern process recipe can involve several or many plasma states, each may require a different ion energy. Thus, the system and method can be adopted for each plasma state in the process recipe to optimize the slope separately.

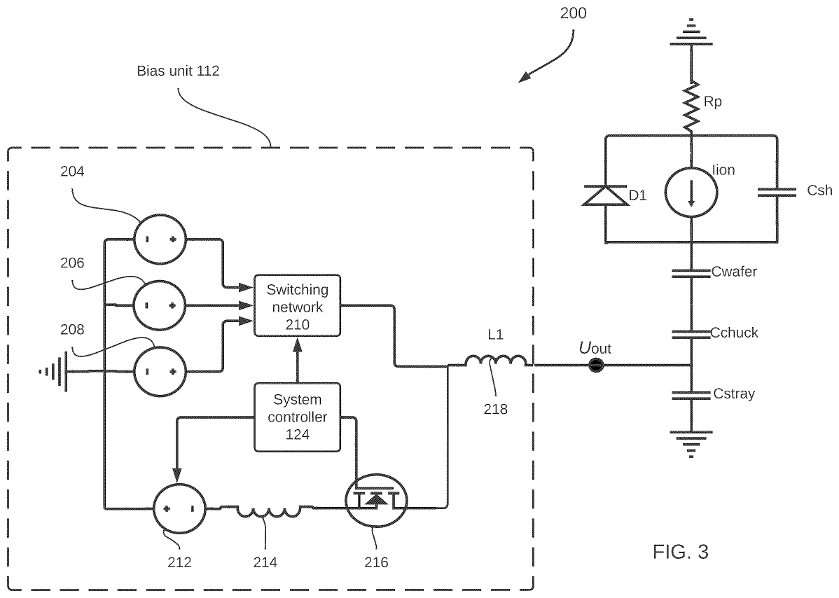

FIG. 3 presents a schematic diagram of an embodiment (200) of the bias unit (112), connected to the plasma process chamber, illustrated by using equivalent electrical circuits. The bias unit (112) comprises a SMPC, exemplarily constructed with three voltage sources: 204, 206, and 208. Each voltage source furnishes a distinct voltage level, correlating with the intended tailored waveform. The SMPC might possess more or fewer voltage sources; one may supply the positive voltage level (V_{d}), while another may offer the negative setting voltage (Vₛ). These voltage sources are connected to a switching network (210), which incorporates switches like MOSFETs. The current source consists of a negative voltage source (212) and an inductor (214). The current source is coupled to chuck (106) through a switch (216), demonstrated exemplarily as a MOSFET. There are numerous methods to formulate a current source, as recognized in the art. The voltage source (212) is connected to the system controller (124), which, in the setting phase, enables the voltage source (212) to generate variant voltages for each pulse, translating into different slopes. Each of the pulses may apply one voltage for the single slope or multiple voltages for MSRP. The voltage generation is controlled by the system controller (124). The bias unit (112) comprises an inductor L₁ (218) placed between the output of the bias unit (112) and the chuck (106).

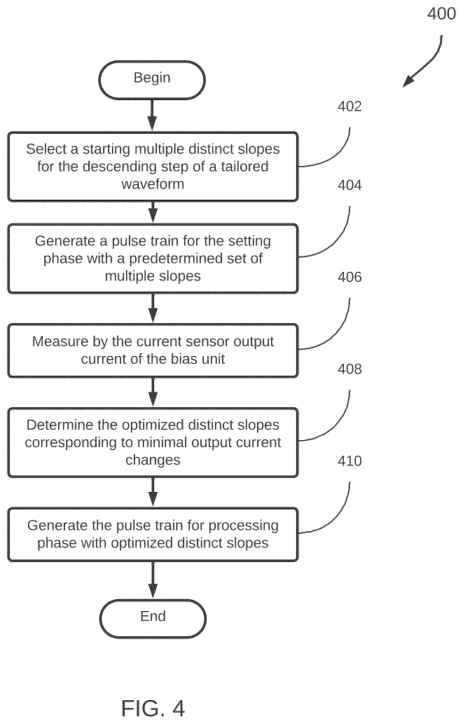

FIG. 4 outlines a flowchart of an exemplary process (400) for determining optimized multiple distinct slopes for the descending step of a tailored waveform. Process 400 begins with step 402, where the system controller (124) selects starting multiple distinct slopes for the setting phase. These starting slopes may be derived from a model or historical data and serve as the basis for generating testing slopes. Various methods can be employed to generate testing slopes from these starting values. For example, the testing slopes might be apex values derived from the starting slopes, with subsequent pulses incrementally increasing or decreasing the slope values. Alternatively, the starting slopes may be positioned as midpoints in an array, with testing slopes generated symmetrically around these midpoints to explore a broader range of slope configurations.

In step 404, the system controller (124) generates a pulse train for the setting phase based on the testing slopes generated in step 402. Step 406 involves the execution of the setting phase by the system controller (124), during which the output currents of the bias unit (112) are measured by the current sensor (122) for each distinct slope. The measured currents are sent to the system controller (124), which determines the optimized multiple distinct slopes in step 408 based on Equation (1).

In one implementation, the optimized multiple distinct slopes are determined by establishing a mathematical model using the measured data, which minimizes the changes in the output current. In another implementation, a lookup table is created, and the optimized multiple distinct slopes are determined by analyzing the table using techniques such as extrapolation and interpolation.

The selected slopes correspond to those yielding the minimal changes in output current as a function of the slopes.

In step 410, the system controller (124) generates a pulse train for the processing phase using the optimized multiple distinct slopes, ensuring consistent and precise ion energy distribution during plasma processing.

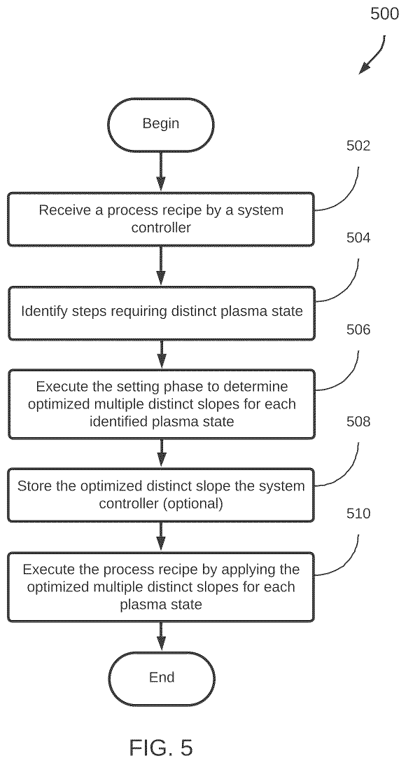

FIG. 5 illustrates a flowchart embodying a method to generate optimized multiple distinct slopes for a process recipe, accommodating steps that require disparate ion currents due to varying plasma states. The process (500) begins with the system controller (124) receiving a process recipe (126) in step 502. In step 504, the controller analyzes the recipe to identify steps associated with different plasma states in the plasma chamber, each requiring distinct ion current control.

Following this analysis, a setting phase is executed in step 506 to determine the optimized multiple distinct slopes for each step, using process 400 as a guide. After the optimized slopes are determined, they are optionally stored in a storage medium within the system controller (124) in step 508.

The process concludes in step 510, where the updated recipe—now incorporating the optimized multiple distinct slopes for the identified steps—is implemented. This methodology provides a robust and automated approach to real-time control and optimization of plasma processes, ensuring that variations in ion current requirements across different plasma states in the recipe are effectively managed. This enhances the precision, consistency, and overall performance of the plasma process chamber.

1. A process system, comprising:
a vacuum chamber configured to process a wafer;
a chuck configured to sustain the wafer;
a bias unit coupled to the chuck, the bias unit further comprising a switched-mode power converter (SMPC), a current source, and a system controller,
wherein the bias unit is configured to generate a tailored waveform comprising a descending step with multiple linear ramp steps, each having distinct slopes to enhance ion energy distribution.

2. The process system of claim 1, wherein the tailored waveform further comprises a positive voltage step and a negative voltage bias setting point, and the descending step ramps down towards a voltage more negative than the setting point.

3. The process system of claim 1, wherein the tailored waveform is used in conjunction with an RF power generator to generate plasma with accelerated ions.

4. The process system of claim 1, wherein the optimized slopes for the tailored waveform are determined during a setting phase of a process recipe by identifying slopes corresponding to minimal changes in the bias unit's output current.

5. The process system of claim 4, wherein the process recipe further comprises a processing phase that utilizes the optimized slopes determined during the setting phase.

6. A process system, comprising:
a vacuum chamber configured to process a wafer;
a chuck configured to sustain the wafer;
a bias unit coupled to the chuck, the bias unit further comprising a SMPC, a current source capable of producing varied currents, and a system controller; and
a current sensor positioned at an output terminal of the bias unit,
wherein the bias unit is configured to generate a tailored waveform comprising a positive voltage step, a negative voltage bias setting point, and a descending step including multiple distinct slopes for enhanced ion energy control;
wherein the system controller is configured to manage the waveform during a setting phase by initiating a pulse train, each pulse in the pulse train comprising a descending step with multiple distinct slopes;
wherein the current sensor measures the output current of the bias unit during the descending step with multiple distinct slopes;
wherein the system controller identifies optimized slopes by detecting minimal changes in the output current as a function of the slopes; and
wherein, during a processing phase, the system controller directs the bias unit to apply a pulse train with the optimized slopes.

7. The process system of claim 6, wherein the current source, under the control of the system controller, generates the distinct slopes for the descending step.

8. The process system of claim 6, wherein the SMPC further includes multiple voltage sources and a switching network for precise waveform generation.

9. The process system of claim 6, wherein the current generated by the current source is adjustable in real-time by the system controller.

10. The process system of claim 6, wherein the pulse train in the setting phase comprises multiple groups of pulses, each group maintaining consistent multiple distinct slopes.

11. The process system of claim 6, wherein the setting phase and the processing phase are executed sequentially within a single process event to optimize ion energy distribution.

12. The system of claim 6, wherein the setting phase and the processing phase are conducted independently, and the optimized slopes are stored for application to process recipes used for multiple wafers.

13. The system of claim 6, wherein the current source comprises a voltage source coupled with an inductor to generate tailored waveforms.

14. A method for generating a voltage bias for accelerating ions in a plasma process chamber, comprising:
receiving, by a system controller, a process recipe;
generating, by the system controller, a first pulse train by a bias unit, the first pulse train comprising a plurality of pulses, each exhibiting a positive voltage step, a negative voltage setting point, and a descending step towards a voltage more negative than the setting point, wherein the descending step includes multiple linear ramp steps with distinct slopes to achieve optimal ion energy distribution;
measuring, by a current sensor, the output current of the bias unit corresponding to each distinct slope;
identifying, by the system controller, optimized distinct slopes corresponding to minimal changes in the output current as a function of varied slopes; and
generating, by the system controller, a second pulse train comprising multiple pulses, wherein the descending steps adopt the optimized distinct slopes.

15. The method of claim 14, further comprising adjusting current of the bias unit's current source, under the control of the system controller, to generate the distinct slopes.

16. The method of claim 14, wherein generating the first and second pulse trains occurs within a single process event for the process recipe.

17. The method of claim 14, wherein generating the first pulse and the second pulse trains occurs as separate process events.

18. The method of claim 14, wherein the optimized distinct slopes are stored by the system controller for subsequent use.

19. The method of claim 14, wherein generating the first pulse train includes subdividing the pulse train into several groups, with each group maintaining consistent multiple distinct slopes.

20. The method of claim 14, wherein the optimized distinct slopes are determined for different plasma states specified in the process recipe.
